(19) United States
(12) Patent Application Publication
(10) Pub. No.: US 2020/0203271 A1
(43) Pub. Date: Jun. 25, 2020

(54) INTERCONNECT STRUCTURE AND METHOD FOR MANUFACTURING THE SAME

(71) Applicant: XIA TAI XIN SEMICONDUCTOR (QING DAO) LTD., Qingdao (CN)

(72) Inventors: HYUNYOUNG KIM, Singapore (SG); DOWON KWAK, Singapore (SG); KANG-WON SEO, Singapore (SG)

(21) Appl. No.: 16/663,381

(22) Filed: Oct. 25, 2019

Related U.S. Application Data
(60) Provisional application No. 62/783,219, filed on Dec. 21, 2018.

(51) Int. Cl. H01L 23/528; H01L 21/02; H01L 21/768; H01L 23/532

(52) U.S. Cl. CPC H01L 23/528; H01L 21/02266; H01L 23/5329; H01L 21/0228; H01L 21/7682

(57) ABSTRACT

A method for manufacturing interconnect structure is disclosed. The method comprises forming a plurality of interconnect features on a surface apart from each other so as to define at least a trench there-between; and performing a physical vapor deposition process using a dielectric material to cover top surfaces of the plurality of interconnect features and seal the at least one trench to form at least one void, wherein the dielectric material includes at least one arch-shaped surface that connects side wall surfaces defining the corresponding trench and defines a concave that opens toward the corresponding void.

### CROSS-REFERENCE TO RELATED APPLICATIONS

This application claims the benefit of U.S. Provisional Patent Application No. 62/783,219 filed on Dec. 21, 2018, which is hereby incorporated by reference herein and made a part of specification.

### FIELD

The present disclosure is generally related to interconnect structure of semiconductor device and method for manufacturing the same, more specifically to interconnect structure in Dynamic Random Access Memory (DRAM) device and method for manufacturing the same.

### BACKGROUND

Modern semiconductor devices are often composed of multi-level conductive lines and dielectrics. Device performance (e.g., speed and power consumption) may be improved when the sizes of the device features are scaled down, which leads to higher feature density. However, higher feature density tends to increase the possibility of cross talking between the conductive lines, due to the distance reduction there-between. Therefore, cross-talk reduction through optimizing the dielectrics arrangement between conductor lines becomes an important topic in semiconductor fabrication.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional view of an interconnect structure in accordance with some embodiments of the instant disclosure.

FIG. 2a through 2c are cross-sectional views illustrating intermediate stages of a method of manufacturing an interconnect structure of a semiconductor device in accordance with some embodiments of the instant disclosure.

FIG. 3a to 3c illustrates cross-sectional views of an interconnect structure in different scales in accordance with some embodiments of the instant disclosure.

FIG. 4 illustrates a relation of some features of an exemplary interconnect structure manufactured by a method of some embodiments according to the instant disclosure.

FIG. 5 illustrates a schematic cross-sectional view of an exemplary semiconductor memory devices that utilizes inventive concepts in accordance with various embodiments of the instant disclosure.

FIG. 6 is a flow chart illustrating a method for manufacturing an interconnect structure of a semiconductor device in accordance with some embodiments of the instant disclosure.

It is to be noted, however, that the appended drawings illustrate only exemplary embodiments of this disclosure and are therefore not to be considered limiting of its scope, for the disclosure may admit to other equally effective embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of layers, regions and/or structural elements may be reduced or exaggerated for clarity. The use of similar or identical reference numbers in the various drawings is intended to indicate the presence of a similar or identical element or feature.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

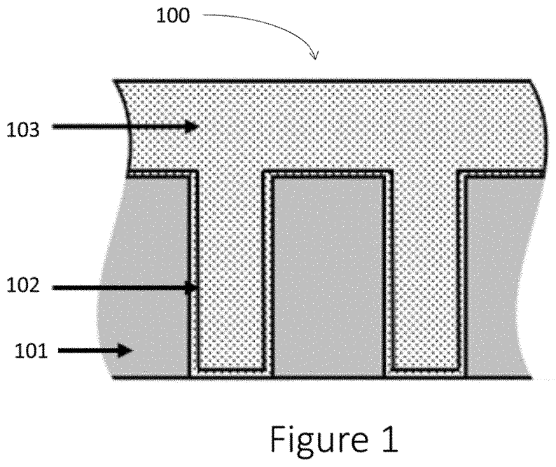

The description will be made as to the exemplary embodiments in conjunction with the accompanying drawings in FIG. 1 to 6. Reference will be made to the drawing figures to describe the present disclosure in detail, wherein depicted elements are not necessarily shown to scale and wherein like or similar elements are designated by same or similar reference numeral through the several views and same or similar terminology.

FIG. 1 illustrates a cross-sectional view of an interconnect structure 100 in accordance with some embodiments of the instant disclosure. The interconnect structure 100 includes a plurality of metal lines 101, a first dielectric layer 102, and a second dielectric layer 103 sequentially deposited over the metal lines 101. In some scenarios, the interconnect structure 100 can be used in semiconductor devices (e.g., a DRAM) after generation below 80 nm.

The first dielectric layer 102 and the second dielectric layer 103 can be deposited conformally by employing deposition methods such as chemical vapor deposition (CVD), atomic layer deposition (ALD), or spin on dielectrics (SOD).

In some embodiments, the materials of the first dielectric layer 102 and the second dielectric layer 103 may be chosen from materials having conventional dielectric constant values (e.g., having dielectric constant value of around 4), such as silane (SiH₄), or tetraethoxysilane (TEOS) based oxides. In other embodiments, the first dielectric layer 102 and the second dielectric layer 103 may employ low dielectric constant (low-K) materials such as fluorine (F)-doped silicon oxide (SiO₂), carbon-doped SiO₂ (e.g., SiOC, SiOCH, pSiOCH), polymers, or a combination thereof. Choices for the low dielectric constant materials may further include black diamond, SiLK™ (by Dow Chemical), hydrogen silesquioxanes (HSQ or HSiO_{1.5}), methyl silsesquioxane (MSQ or CH₃SiO_{1.5}), polyarelene, and Teflon® AF amorphous fluoroplastics (by DuPont), . . . etc.

Comparing to other scenario using conventional dielectric material (e.g., with dielectric constant about 4), using low dielectric constant materials with dielectric constant smaller than 2.8 for the first dielectric layer 102 and the second dielectric layer 103 may help reduce a capacitive coupling between the metal lines 101 and improve RC-delay property of the interconnect structure 100 in a semiconductor device.

When using the doped silicon based low dielectric constant materials (e.g., silicon based material with carbon, hydrogen components) via CVD or ALD process to form the first dielectric layer 102 and the second dielectric layer 103, reaction byproducts such as carbon, hydrogen, and chlorine may be generated. In addition, using CVD or ALD process to form SiO₂ dielectric films (e.g., the second dielectric layer 103) may require additional reduction gases such as N₂O, O₂. Accordingly, SiO₂ dielectric films containing carbon, hydrogen, chlorine and volatiles are generated. Such reaction may be described by the following formulas.

SiH₄+N₂O→SiOxHy+other volatiles

Si(OC₂H₅)₄+O₂→SiOxCyHz+other volatiles

Consequently, in some scenario, post treatments may be required to eliminate the reaction byproducts. Suitable post treatments may include baking, curing or plasma treatment. However, unsuccessful post treatment may occur in the case of overly narrow space between adjacent metal lines 101. Moreover, in some scenarios, a layer under the interconnect structure 100 might not be able to withstand an elevated heat budget from the post treatments.

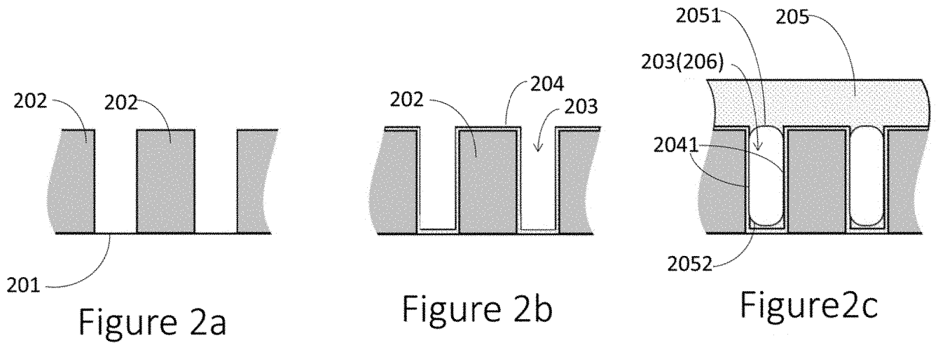

FIG. 2a through 2c are cross-sectional views illustrating intermediate stages of a method of manufacturing an interconnect structure of a semiconductor device in accordance with some embodiments of the instant disclosure.

Referring to FIG. 2a, a conductive layer (not shown) is patterned to form a plurality of conductive features 202 (such as conductive lines, as seen in a lateral cross section) on a surface 201. As shown in FIG. 2a, the conductive features 202 are arranged apart from each other with predetermined separation there-between. Material choice for the conductive features 202 may selectively include tungsten, aluminum, and copper. In some embodiments, conductive features 202 may include tungsten, aluminum, copper, or a combination thereof.

Referring to FIG. 2b, a conformal layer 204 may be formed to conformally cover the respective top and sidewall surfaces of the plurality of conductive features 202. The conformal layer 204 does not fill the gap between adjacent ones of the conductive features 202, thus defining a plurality of trenches 203 there-between. The conformal layer 204 may contribute to protecting the conductive lines 202 from surface oxidation and deformation.

The conformal layer 204 may be formed using a film-forming technique that exhibits a good step coverage property, for example, Atomic Layer Deposition (ALD), Chemical Vapor Deposition (CVD), Plasma enhanced Chemical Vapor Deposition (PECVD), or Spin on Dielectrics (SOD) process with SiH₄, TEOS or low dielectric constant materials.

In some embodiments of the instant disclosure, the materials of the conformal layer 204 may include (but not limited to) carbon doped SiO₂ (SiOC, SiOCH, pSiOCH), Black diamond, SiLK, Hydrogen Silesquioxanes (HSQ, HSiO_{1.5}), Methyl silsesquioxane (MSQ, CH₃SiO_{1.5}), Polyarelene, and Teflon AF. In some embodiments of the instant disclosure, the materials of the conformal layer 204 can be selected from a group consisting materials capable to protect the conductive lines 202 from surface oxidation and deformation. In some embodiments, a diffusion barrier layer is further formed between the conductive features 202 and the conformal layer 204.

In some embodiment, the conformal layer 204 may be formed via ALD process using a precursor including a combination of DilsoPropylAminoSilane (DIPAS) and BisDiEthylAminoSilane (BDEAS). Instead of using CVD, forming the conformal layer 204 via ALD can be beneficial to scale down features in semiconductor devices. Particularly, forming the conformal layer 204 via ALD can achieve lower thickness and higher uniformity of the conformal layer 204, so as to optimize (for example, maximize) the size of the voids 206 that will be described below. In some embodiments of the instant disclosure, a thickness of the conformal layer 204 may be less than 30 nm.

Referring to FIG. 2c, a dielectric material 205 may be formed on the conformal layer 204 to seal the openings of the trenches 203 and form voids 206. In some embodiments, the dielectric material 205 may be disposed through physical vapor deposition (PVD) process.

In some embodiments, when performing the PVD process, a solid phase material containing Si, SiO₂, or a combination thereof may be used as a source target. In one embodiment, the solid phase material contains Si. In one embodiment, the solid phase material contains SiO₂. In one embodiment, the solid phase material contains Si and SiO₂. The target may be a tablet type, a granular type, and a powder type or a combination thereof. The dielectric material 205 formed by PVD methods using Si, SiO₂, or a combination thereof as the source target may be substantially free from carbon, hydrogen and chlorine content. Accordingly, it is possible to distinguish CVD or ALD dielectrics from PVD dielectrics through various thin film analysis methods such as FTIR, XPS. The absence of reaction byproduct such as carbon and hydrogen may reduce unforeseeable variation of electrical characteristics. In some embodiments, a thickness of the dielectric material 205 may be less than 1 μm.

Since the voids 206 (which may be vacuum or contain air, which has a low dielectric constant of about 1) are formed between adjacent ones of the conductive lines 202, it is possible to achieve less capacitive coupling between the conductive lines 202 and better RC-delay property of a semiconductor device than that of the embodiment illustrated in FIG. 1.

Referring to FIG. 2c, which shows a process of using PVD method to form the dielectric material 205. Comparing to using CVD and ALD methods, the PVD-formed dielectric material offers reduced step coverage, thereby enabling the generation of a maximized volume of the voids 206 with reduced variations in the portion of dielectric material 205 that precipitates into a bottom portion of the trenches 203. Due to the characteristics of PVD deposition, a non-conformal deposition shape may results in nearly zero deposition at sidewall surfaces of conductive lines 202.

Different PVD deposition systems may generate different profiles for the voids 206 (as well as different trench bottom dielectric residual profiles/volumes). In one example embodiment, the dielectric material 205 can be deposited using a sputtering deposition process or an electron beam evaporation deposition process. In addition, different PVD process parameters (such as a distance between target and wafer, pressure, and power setting) may also affect the profile of the voids 206.

For example, in order to form a specific profile of the voids 206 (such as that shown in the instant figures), when setting parameters in a sputtering deposition process for forming the dielectric material 205, a target to substrate distance may be set from about 5 mm to 300 mm, a chamber pressure maybe set from about 1×10⁻³ torr to 10 torr. A power used in the sputtering deposition process can be DC magnetron, DC/RF magnetron, or DC/RF pulsed. During sputtering deposition process, processing gas such as Ar or O₂ may be used. In the case of setting parameters for an electron beam evaporation deposition for forming the dielectric material 205, a target to substrate distance may be set from about 500 mm to 1.5 m, a chamber pressure maybe set from about 1×10⁻⁸ torr to 1×10⁻⁶ torr.

In the embodiment illustrated in FIG. 2c, when the dielectric material 205 is formed by PVD under the abovementioned parameters/conditions, a middle portion of side wall surfaces 2041 defining the corresponding trench 203 may be substantially free form the dielectric material 205. Besides, said specific profile may have a substantially uniform width.

Said specific profile of the voids 206 may be further defined by the dielectric material 205 deposited respectively in the top portion and the bottom portion of the trenches 203 region. In some embodiment, the dielectric material 205 may include a plurality of arch-shaped surface 2051 respectively covering a corresponding one of the trenches 203 that connecting the side wall surfaces 2041 defining the corresponding trench 203. Furthermore, the arch-shaped surface 2051 defines a concave that opens downwardly toward the corresponding void 206. Besides, the dielectric material 205 includes an arch-shaped surface 2052 in the bottom portion of the trenches 203 that connects the side wall surfaces 2041 defining the corresponding trench 203 and defines a concave that opens upwardly toward the corresponding void 206.

In some scenarios, when fabricating a nano-scaled semiconductor device, even if there are variations between various trenches 203 width, using electron beam evaporation systems (such as EVATEC co. ltd.) to form the dielectric material 205 may achieve nearly zero deposition of dielectric material 205 in the bottom potion of the trenches 203. In some cases, the dielectric material 205 may not be deposited in the bottom portion of the trenches 203 region.

In some embodiments, the step of forming the conformal layer 204 can be optional. In the other words, the dielectric material 205 may be deposited directly on the conductive lines 202 to form the voids 206, in such scenario, the voids 206 may be defined directly by side wall surfaces of adjacent ones of the conductive lines 202.

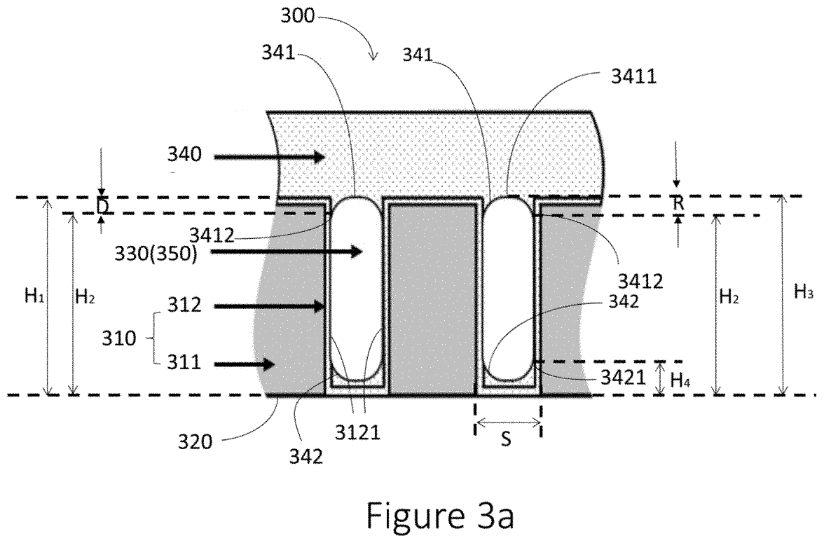

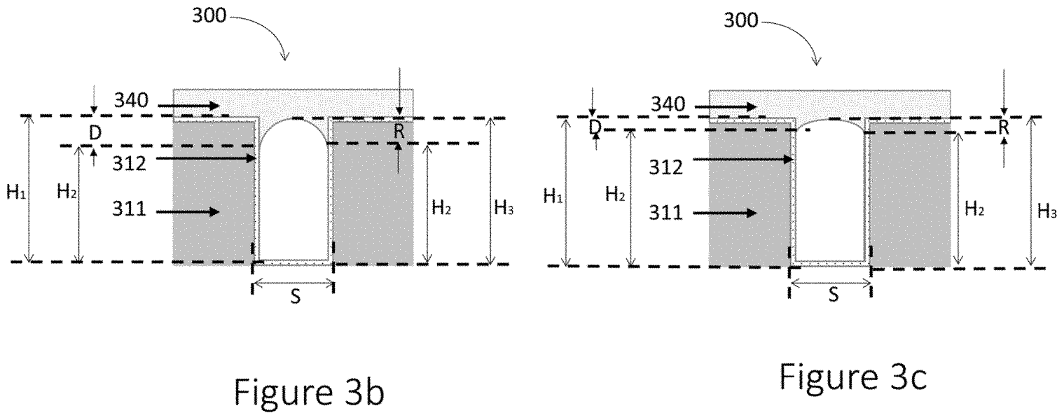

The arrangement of trench 203 width (related to the spacing between conductive lines 202) may also affect the profile of the voids 206 and the amount of dielectric material 205 deposited in the bottom portion of the trenches 203. More detail of the relation between trench 203 width and the profile of the voids 206 will be described with FIG. 3a to 3c.

FIG. 3a to 3c illustrates three cross-sectional views corresponding respectively to an exemplary interconnect structure 300 in three different scales in accordance with some embodiments of the instant disclosure. The interconnect structure 300 may be manufactured using inventive concept in accordance of some embodiments in the instant disclosure.

Referring to FIG. 3a, which illustrate a interconnect structure 300 comprising a plurality of interconnect features 310 arranged on a surface 320 abreast each other defining at least one trench 330 there-between, and a dielectric material 340 formed on top surfaces of the plurality of interconnect features 310. The dielectric material 340 seals the at least one trench 330 to define at least one void 350.

In the embodiment, the dielectric material 340 formed by PVD methods using Si, SiO₂, or a combination thereof as target may substantially free from generally carbon and hydrogen contents.

In the embodiment, the plurality of interconnect features 310 comprises a plurality of conductive lines 311 and a conformal layer 312 formed on the plurality of conductive lines 311. In some embodiments, the conformal layer 312 can be optional.

In the example embodiment, a middle section of side wall surfaces 3121 of the interconnect features 310 defining the at least one trench 330 is substantially free from the dielectric material 340 coverage. The dielectric material 340 may separately covers top surfaces of the plurality of interconnect features 310 and a bottom surface defining the at least one trench 330, respectively. The dielectric material 340 may include at least one upper boundary surface 341 that connects the side wall surfaces 3121 defining the corresponding trench 330 and at least one lower boundary surface 342 that connects the side wall surfaces 3121 defining the corresponding trench 330. The upper boundary surface 341 may be arch-shaped that defines a concave that opens downwardly toward the corresponding void 350. The lower boundary surface 342 may be arch-shaped that defines a concave that opens upwardly toward the corresponding void 350. In the embodiment, a shape of a cross section of the void 350 is a projection of a spherocylinder. In some scenario, the bottom surface defining the at least one trench 330 can be free from the dielectric material 340.

Different profiles of the voids 350 can be achieved by arranging a spacing S between the adjacent ones of the conductive lines 311, a height H₁ of the interconnect features 310, and the PVD system used for depositing the dielectric material 340. Different profiles of the voids 350 will be introduced in the embodiments respectively illustrated in FIG. 3a to 3c.

Referring to FIG. 3a, which illustrate interconnect structure 300 having a spacing S between the adjacent ones of the conductive lines 311 less than 300 nm and a height H₁ of the interconnect features 310 more than 150 nm. Consequently, a height H₂ of the lowest point 3412 of a cross section of the upper boundary surface 341 is more than 85 percent of the height H₁ of the interconnect features 310. Besides, when an opening deposition depth D (H₁ minus H₂) is defined by the difference between the height H₁ of the interconnect features 310 and a height H₂ of the lowest point 3412 of a cross section of the upper boundary surface 341, a ratio (D/H₁) between the opening deposition depth D and the height H₁ of the interconnect features 310 is less than 15 percent. Besides, when a rise R (H₃ minus H₂) is defined by the difference between a height H₃ of a highest point 3411 and a height H₂ of the lowest point 3412 of a cross section of the upper boundary surface 341, the rise R is less than 15 percent of a height H₁ of the interconnect features 310. As previously mentioned, the amount of the dielectric material 340 that covers bottom surface defining the at least one trench 330 is affected by the system of PVD being used when forming the dielectric material 340. In this embodiment, when the dielectric material 340 is formed by sputtering, a height H₄ of the highest point 3421 of a cross section of the lower boundary surface 342 is less than 10 percent of the height H₁ of the interconnect features 310. In some scenario, when the dielectric material 340 is formed by electron beam evaporation, the height H₄ of the highest point 3421 is less than 5 percent of the height H₁ of the interconnect features 310.

FIG. 3b illustrates a interconnect structure 300 that can be employed in semiconductor devices with scale small than 100 nm. In the interconnect structure 300 illustrated in FIG. 3b, the spacing S can be less than 80 nm and the height H₁ can be more than 150 nm. Consequently, the height H₂ is more than 95 percent of the height H₁. Besides, a ratio (D/H₁) between the opening deposition depth D (H₁ minus H₂) and the height H₁ is less than 5 percent. The rise R (H₃ minus H₂) is less than 5 percent of the height H₁. In this embodiment, when the dielectric material 340 is formed by sputtering, the height H₄ (not shown in the schematic diagram FIG. 3b) is less than 3 percent of the height H₁. In some scenario, when the dielectric material 340 is formed by evaporation, the a height of the highest point of a cross section of the lower boundary surface (not shown in the schematic diagram FIG. 3b) is less than 1 percent of the height H₁.

FIG. 3c illustrates a interconnect structure 300 that can be employed in semiconductor devices with scale small than 50 nm. In the interconnect structure 300 illustrated in FIG. 3c, the spacing S can be less than 40 nm and the height H₁ can be more than 100 nm. The width of the conductive lines 311 can be less than 50 nm. Consequently, referring to FIG. 3c, the height H₂ is more than 98 percent of the height H₁. Besides, a ratio (D/H₁) between the opening deposition depth D (H₁ minus H₂) and the height H₁ is less than 2 percent. The rise R is less than 2 percent of a height H₁. In this embodiment, no matter the dielectric material 340 is formed by sputtering or evaporation, a height of the highest point of a cross section of the lower boundary surface (not shown in the schematic diagram FIG. 3c) is less than 1 percent of the height H₁ of the interconnect features 310.

When utilizing the inventive concept in accordance with the instant disclosure, the device performance relating to RC delay or cross talk between conductor lines maybe improved by over 5%.

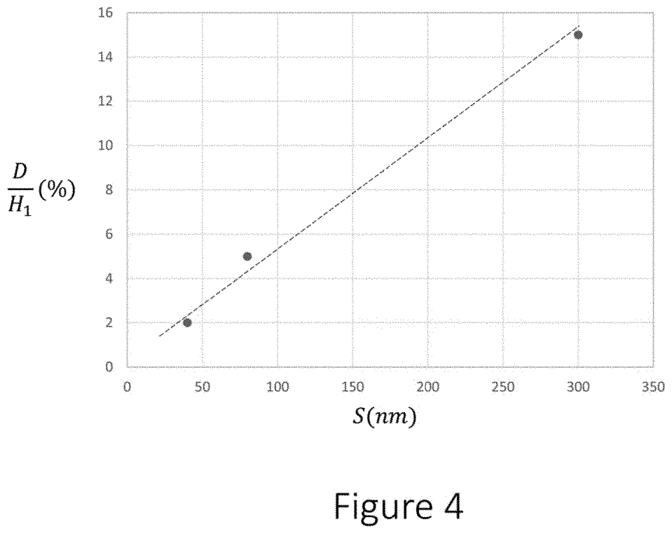

FIG. 4 illustrates a relation of a ratio between the opening deposition depth D and the height H₁ of the interconnect features 310 versus the spacing S of an interconnect structure manufactured according to some embodiments of the instant disclosure.

Referring to FIG. 4, which is a plot that depicts the relation between the spacing S and the ratio (D/H₁) between the opening deposition depth D and the height H₁ of the interconnect features 310. It is found that the ratio (D/H₁) between the depth D and the height H₁ is substantially proportional to the spacing S between the adjacent ones of the conductive features (such as feature 311 shown in FIG. 3).

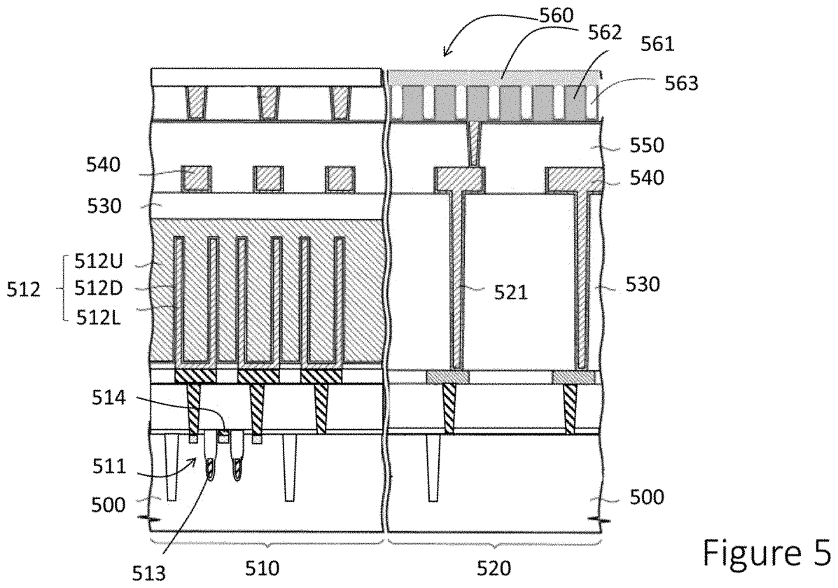

FIG. 5 illustrates a schematic cross-sectional view of an exemplary semiconductor memory devices that utilizes inventive concepts in accordance with various embodiments of the instant disclosure.

Referring to FIG. 5, defined on a semiconductor substrate 500 may be a cell region 510 (including a plurality of memory cells) and a peripheral circuit region 520 (in which peripheral circuits controlling the memory cells are formed).

Each of the memory cells on the cell region 510 may include a transistor 511 and a capacitor 512. In some example embodiments, word lines 513 and bit lines 514 may be provided in the cell region 510 of the semiconductor substrate 500 to cross each other, and capacitors 512 may be formed over the word lines 513 and bit lines 514. The capacitor 512 may be electrically connected to the transistor 511 through contact plugs. In example embodiment, the capacitors 512 may include a lower electrode 512L, an upper electrode 512U, and a dielectric 512D there-between. In some example embodiments, the lower electrodes 512L of the capacitors 512 may have a cylindrical or pillar-shaped structure.

An insulating layer 530 may be formed on the semiconductor substrate 500 to cover the capacitors 512 and the peripheral circuits (not shown). A contact plug 521 may be in the insulating layer 530. In some example embodiments, lower interconnection lines 540 may be disposed on the insulating layer 530. The lower interconnection lines 540 may be electrically connected to the capacitors 512 or the peripheral circuits (not shown). A width of the lower interconnection line 540 and a space between the adjacent lower interconnection lines 540 on the cell region 510 may be different from that on the peripheral circuit region 520.

A dielectric layer 550 may be formed on the insulating layer 530 to cover the lower interconnection lines 540.

A interconnect structure 560 may be formed on the dielectric layer 550 in the peripheral circuit region 520. The interconnect structure 560 may be formed using the method of manufacturing a semiconductor device, according to some example embodiments of the present disclosure. For example, the interconnect structure 560 comprising a plurality of interconnect features 561 abreast each other, a dielectric material 562 formed on top surfaces of the plurality of interconnect features 561, wherein the dielectric material 562 defines a plurality of voids 563.

The interconnect features 561 may be electrically connected to the lower interconnection lines 540 through via plugs penetrating the dielectric layer 550.

In the embodiment, the voids 563 may be formed on the peripheral circuit region 520. In some embodiments, the voids 563 may be formed on both of the cell region 510 and the peripheral circuit region 520.

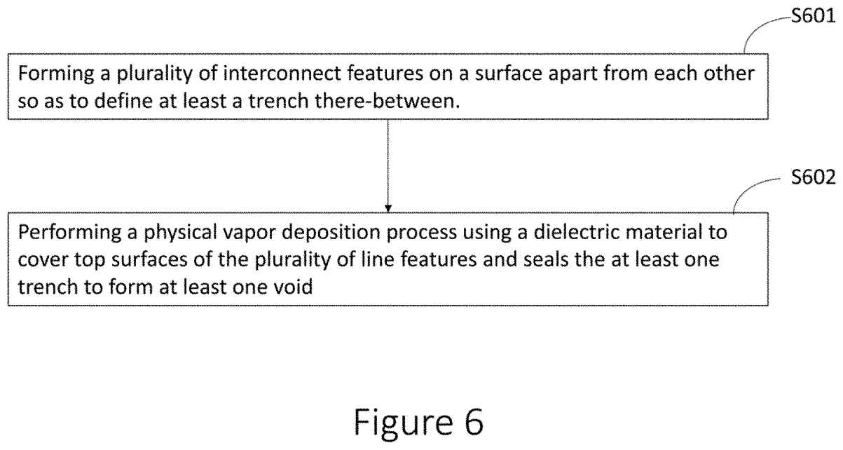

One aspect of the instant disclosure provides a method for manufacturing interconnect structure. FIG. 6 is a flow chart illustrating the method which comprises comprising processes S601 and S602.

Process S601: Forming a plurality of interconnect features on a surface apart from each other so as to define at least a trench there-between.

In some embodiments of the instant disclosure, the step S601 further comprises patterning to form a plurality of conductive lines on the surface, and forming a conformal layer on the plurality of conductive lines using ALD with a precursor including a combination of DiIsoPropylAminoSilane (DIPAS) and BisDiEthylAminoSilane (BDEAS).

In some embodiments of the instant disclosure, in step S601, forming a conformal layer can be optional.

Process S602: Performing a PVD process using a dielectric material to cover top surfaces of the plurality of interconnect features and seal the at least one trench to form at least one void, wherein the dielectric material includes at least one arch-shaped surface that connects side wall surfaces defining the corresponding trench and defines a concave that opens toward the corresponding void.

In some embodiments of the instant disclosure, the dielectric material separately covers top surfaces of the plurality of interconnect features and a bottom surface defining the at least one trench respectively.

In some embodiments of the instant disclosure, the process S602 further comprises using a solid phase material containing Si, SiO₂, or a combination thereof.

In some embodiments of the instant disclosure, process S602 further comprising setting a target to substrate distance more than 5 mm, setting a chamber pressure higher than 1×10⁻³ torr; and performing a sputtering deposition process.

In some embodiments of the instant disclosure, the step S602 further comprising setting a target to substrate distance more than 500 mm, setting a chamber pressure higher than 1×10⁻⁸ torr, and performing an electron beam evaporation deposition process.

Another aspect of instant disclosure provides an interconnect structure, which comprises a plurality of interconnect features arranged on a surface abreast each other defining at least one trench there-between; and a dielectric material formed on top surfaces of the plurality of interconnect features, wherein the dielectric material seals the at least one trench to define at least one void. A middle section of side wall surfaces of the interconnect features defining the at least one trench is substantially free from the dielectric material coverage.

In some embodiments, the dielectric material separately covers top surfaces of the plurality of interconnect features and a bottom surface defining the at least one trench, respectively.

In some embodiments, the plurality of interconnect features comprises a plurality of conductive lines.

In some embodiments, the plurality of interconnect features further comprises a conformal layer formed on the plurality of conductive lines.

In some embodiments, a spacing between adjacent ones of the conductive lines is less than 300 nm. The dielectric material includes at least one upper boundary surface that connects the side wall surfaces defining the corresponding trench, wherein a rise between a lowest point and a highest point of a cross section of the upper boundary surface is less than 15 percent of a height of the interconnect features.

In some embodiments, an opening deposition depth is defined by the difference of a height of the lowest point of a cross section of the upper boundary surface and a height of the interconnect features. A ratio between the opening deposition depth and the height of the interconnect features is substantially proportional to the spacing.

In some embodiments, the boundary surface is arch-shaped that defines a concave that opens toward the corresponding void. The spacing between adjacent ones of the plurality of conductive lines is less than 80 nm. The rise between a highest point and a lowest point of a cross section of the upper boundary surface is less than 5 percent of a height of the interconnect features.

In some embodiments, the dielectric material further includes at least one lower boundary surface that connects the side wall surfaces defining the corresponding trench, wherein the height of a highest point of a cross section of the lower boundary surface is less than 3 percent of a height of the interconnect features.

In some embodiments, the upper boundary surface is arch-shaped that defines a concave that opens toward the corresponding void. The spacing between adjacent ones of the plurality of conductive lines is less than 40 nm. The rise between a highest point and a lowest point of a cross section of the upper boundary surface is less than 2 percent of a height of the interconnect features.

In some embodiments, the dielectric material further includes at least one lower boundary surface that connects the side wall surfaces defining the corresponding trench, wherein the height of a highest point of a cross section of the lower boundary surface is less than 1 percent of the height of the interconnect features.

Another aspect of instant disclosure provides an interconnect structure, which comprises a plurality of interconnect features on a surface defining at least one trench; and a dielectric material formed on the plurality of interconnect features to seal the at least one trench and define at least one void, wherein the dielectric material is substantially free from carbon and hydrogen.

In some embodiments, the dielectric material separately covers top surfaces of the plurality of interconnect features and a bottom surface defining the at least one trench, respectively.

In some embodiments, a shape of a cross section of the at least one void is a projection of a spherocylinder.

The embodiments shown and described above are only examples. Many details are often found in the art such as the other features of a radiation measurement panel and device. Therefore, many such details are neither shown nor described. Even though numerous characteristics and advantages of the present technology have been set forth in the foregoing description, together with details of the structure and function, the disclosure is illustrative only, and changes may be made in the detail, especially in matters of shape, size, and arrangement of the parts within the principles, up to and including the full extent established by the broad general meaning of the terms used in the claims. It will therefore be appreciated that the embodiments described above may be modified within the scope of the claims.

What is claimed is:

1. A method for manufacturing interconnect structure, comprising:
forming a plurality of interconnect features on a surface apart from each other so as to define at least a trench there-between; and
performing a physical vapor deposition (PVD) process using a dielectric material to cover top surfaces of the plurality of interconnect features and seal the at least one trench to form at least one void, wherein the dielectric material includes at least one arch-shaped surface that connects side wall surfaces defining the corresponding trench and defines a concave that opens toward the corresponding void.

2. The method of claim 1, wherein the dielectric material separately covers top surfaces of the plurality of interconnect features and a bottom surface defining the at least one trench respectively.

3. The method of claim 1, wherein the forming the plurality of interconnect features comprises patterning to form a plurality of conductive lines on the surface.

4. The method of claim 3, wherein the forming the plurality of interconnect features further comprises:
forming a conformal layer on the plurality of conductive lines using Atomic Layer Deposition (ALD) with a precursor including a combination of DilsoPropylAminoSilane (DIPAS) and BisDiEthylAminoSilane (BDEAS).

5. The method of claim 1, wherein the performing the PVD process comprises:
setting a target to substrate distance more than 5 mm;
setting a chamber pressure higher than 1×10⁻³ torr; and
performing a sputtering deposition process.

6. The method of claim 1, wherein the performing the PVD process comprises:
setting a target to substrate distance more than 500 mm;
setting a chamber pressure higher than 1×10⁻⁸ torr; and
performing an electron beam evaporation deposition process.

7. The method of claim 1, wherein the performing the PVD process comprises using a solid phase material containing Si, SiO₂, or a combination thereof.

8. An interconnect structure, comprising:
a plurality of interconnect features arranged on a surface abreast each other defining at least one trench there-between; and
a dielectric material formed on top surfaces of the plurality of interconnect features, wherein the dielectric material seals the at least one trench to define at least one void;
wherein a middle section of side wall surfaces of the interconnect features defining the at least one trench is substantially free from the dielectric material coverage.

9. The structure of claim 8, wherein the dielectric material separately covers the top surfaces of the plurality of interconnect features and a bottom surface defining the at least one trench, respectively.

10. The structure of claim 8, wherein the plurality of interconnect features comprises a plurality of conductive lines.

11. The structure of claim 10, wherein the plurality of interconnect features further comprises a conformal layer formed on the plurality of conductive lines.

12. The structure of claim 10, wherein
a spacing between adjacent ones of conductive lines is less than 300 nm; and
the dielectric material includes at least one upper boundary surface that connects the side wall surfaces defining the corresponding trench, wherein a rise between a lowest point and a highest point of a cross section of the upper boundary surface is less than 15 percent of a height of the interconnect features.

13. The structure of claim 12, wherein
an opening deposition depth is defined by the difference of a height of the lowest point of the cross section of the upper boundary surface and the height of the interconnect features; and
a ratio between the opening deposition depth and the height of the interconnect features is substantially proportional to the spacing.

14. The structure of claim 12, wherein
the at least one upper boundary surface is arch-shaped that defines a concave that opens toward the corresponding void;
the spacing between adjacent ones of the plurality of conductive lines is less than 80 nm; and
the rise between the highest point and the lowest point of the cross section of the upper boundary surface is less than 5 percent of the height of the interconnect features.

15. The structure of claim 14, wherein the dielectric material further includes at least one lower boundary surface that connects the side wall surfaces defining the corresponding trench, wherein a height of a highest point of a cross section of a lower boundary surface is less than 3 percent of the height of the interconnect features.

16. The structure of claim 12, wherein
the at least one upper boundary surface is arch-shaped that defines a concave that opens toward the corresponding void;
the spacing between adjacent ones of the plurality of conductive lines is less than 40 nm; and
the rise between the highest point and the lowest point of the cross section of the upper boundary surface is less than 2 percent of the height of the interconnect features.

17. The structure of claim 16, wherein the dielectric material further includes at least one lower boundary surface that connects the side wall surfaces defining the corresponding trench, wherein a height of a highest point of a cross section of a lower boundary surface is less than 1 percent of the height of the interconnect features.

18. An interconnect structure, comprising:
a plurality of interconnect features on a surface defining at least one trench; and
a dielectric material formed on the plurality of interconnect features to seal the at least one trench and define at least one void, wherein the dielectric material is substantially free from carbon and hydrogen.

19. The structure of claim 18, wherein the dielectric material separately covers top surfaces of the plurality of interconnect features and a bottom surface defining the at least one trench, respectively.

20. The structure of claim 18, wherein a shape of a cross section of the at least one void is a projection of a spherocylinder.
